(19) United States
(12) Patent Application Publication
(10) Pub. No.: US 2002/0057113 A1
(43) Pub. Date: May 16, 2002

(54) Phase detector

(76) Inventor: Ernst Mullner, Muenchen (DE)

Correspondence Address: BELL, BOYD & LLOYD, LLC, P. O. BOX 1135, CHICAGO, IL, 60690-1135, US

(21) Appl. No.: 09/928,807

(22) Filed: Aug. 13, 2001

(30) Foreign Application Priority Data
Aug. 11, 2000 (DE) 100 39 421.3

(51) Int. Cl. H03D 13/00

(52) U.S. Cl. 327/12

(57) ABSTRACT

A phase detector wherein binary signals are supplied to inputs of an asymmetric circuit having two EXOR elements, the output voltage of the phase detector being proportional to the phase difference between the input signals by a subtraction of the output signals of two EXOR elements and subsequent low-pass filtering, and the subtraction is conducted in such a manner that there is no longer an error, due to the internal propagation delays of the EXOR elements, for determining the phase difference. In particular, the equal-phase condition between the input signals is determined accurately and by a simple voltage comparison with a threshold value selected by the expert, and the range of determination of greater phase differences between binary signals can be extended by the circuit proposed.

### BACKGROUND OF THE INVENTION

The present invention relates to a phase detector for determining a phase difference between a first binary signal and a second binary signal.

To determine the phase differences between two binary signals, EXOR (exclusive or) elements are used. The most well known circuits are based on an arrangement having a single EXOR element or two symmetrically arranged EXOR elements.

From German patent specification DE 197 17 586 C1, a phase detector circuit for high data rates is known in which two EXOR elements are used. Equal treatment of the signals on both data paths results in high stability.

Due to the delay differences at inputs of the EXOR elements, however, an error δ and, respectively, 2δ (FIG. 4) occurs at the output of two symmetrically arranged EXOR elements, which error degrades the phase detector characteristic during detection of the equal-phase condition.

An object of the present invention, therefore, is to find a way of determining the phase differences more accurately.

### SUMMARY OF THE INVENTION

In comparison with known EXOR circuits, an asymmetric arrangement including two EXOR circuits and an inversion of an input or output signal in one EXOR is proposed. The inversion can be done in accordance with various embodiments which, however, lead to the same result with respect to the phase detector characteristic.

The two logical EXOR output signals are subtracted from one another by the inversion at one EXOR. The measurement error δ and, respectively, 2δ is completely suppressed due to this subtraction. For this reason, there is no longer any uncertainty in determining the equal-phase condition.

The characteristic of the entire circuit, which is obtained by combining the analog EXOR output voltages, is directly proportional to the phase difference between the input signals, and it forms an asymmetric linear region as phase detector characteristic wherein its zero transition defines the equal-phase condition of the input signals. In symmetric circuits, detection of the minimum would be required for determining the equal-phase condition. In the novel asymmetric arrangement, it is only necessary to detect a simple threshold value (zero transition according to the theory) of the phase detector characteristic.

Furthermore, the linear region of the output voltage can be expanded by using at least one delay section (inverter) so that a wider phase difference region can be detected.

Additional features and advantages of the present invention are described in, and will be apparent from, the following detailed description of the invention and the figures.

### BRIEF DESCRIPTION OF THE FIGURES

FIG. 1 shows a basic circuit diagram of the phase detector of the present invention;

FIG. 2 shows a basic circuit diagram of the first variant of the inversion;

FIG. 3 shows a basic circuit diagram of the second variant of the inversion;

FIG. 4 shows the phase detector characteristic for a symmetric circuit and an asymmetric circuit;

FIG. 5 shows a circuit diagram for expanding the region of phase difference;

FIG. 6 shows a phase detector characteristic with expansion of the region of phase difference; and

FIG. 7 shows an implementation of the phase detector in CMK technology.

### DETAILED DESCRIPTION OF THE INVENTION

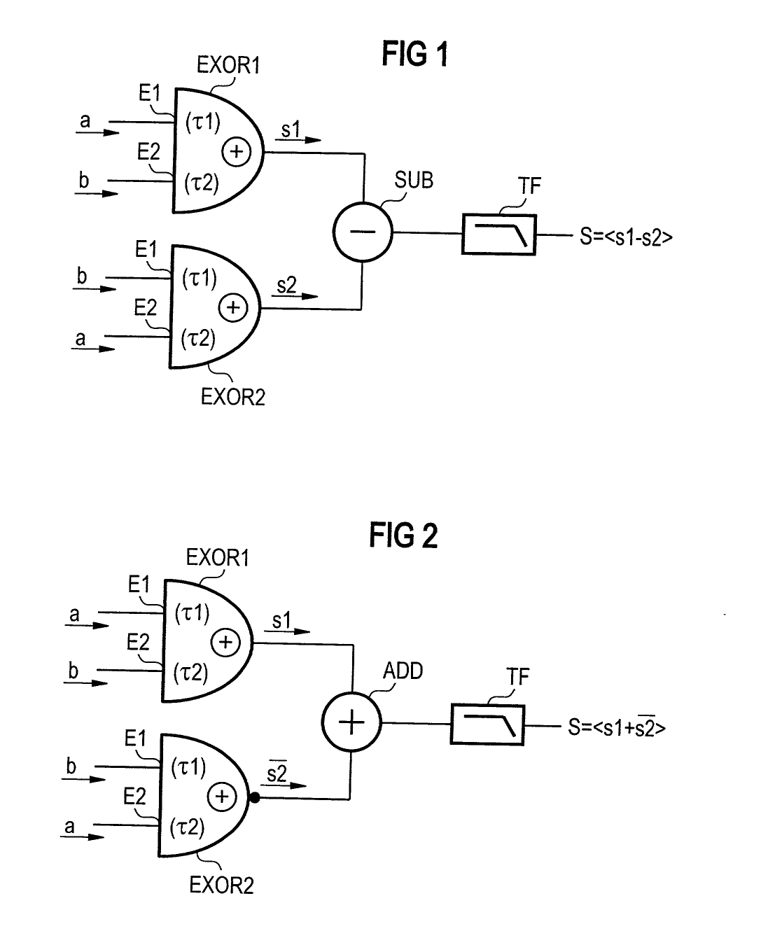

FIG. 1 shows a basic circuit diagram of the phase detector of the present invention. The circuit has two EXOR elements EXOR1, EXOR2, each having two inputs. The first inputs of each EXOR element delay the signals by a first delay τ1 and the second inputs delay the signals by a second delay τ2. A binary signal a and a binary signal b are conducted to the first input E1 in each case of the two EXOR elements. The same signals a and b are conducted to the second input E2 in each case of the EXOR elements, in the reverse order from inputs E1. Assume input signal a is delayed by the delay τ1 at the first EXOR gate EXORI and by the delay τ2 at the second EXOR gate EXOR2, and the input signal b is delayed by the delay τ2 at the first EXOR gate EXOR1 and by the delay τ1 at the second EXOR gate EXOR2. The output signals sI and s2 of the EXOR elements are analog-subtracted via a subtractor SUB. A control voltage S is obtained by time-averaging the output voltages s1-s2 via of a low-pass filter TF. This control voltage S corresponds to exactly the desired phase detector characteristic for determining the phase difference between the signals a and b.

FIG. 2 shows a first variant of the novel phase detector. The bas/ic circuit is similar to that of FIG. 1 but has inversion of the output signal s2 and an adder circuit ADD instead of a subtractor SUB (FIG. 1). This inversion, followed by addition, is equivalent to the previous subtraction in FIG. 1 with respect to the output voltage. The EXOR element in which the inversion is implemented is an EXOR element according to the prior art. The phase detector characteristic can be described, therefore, as

$${S}_{asym} = < s1 + {s}^{v} 2 > .$$

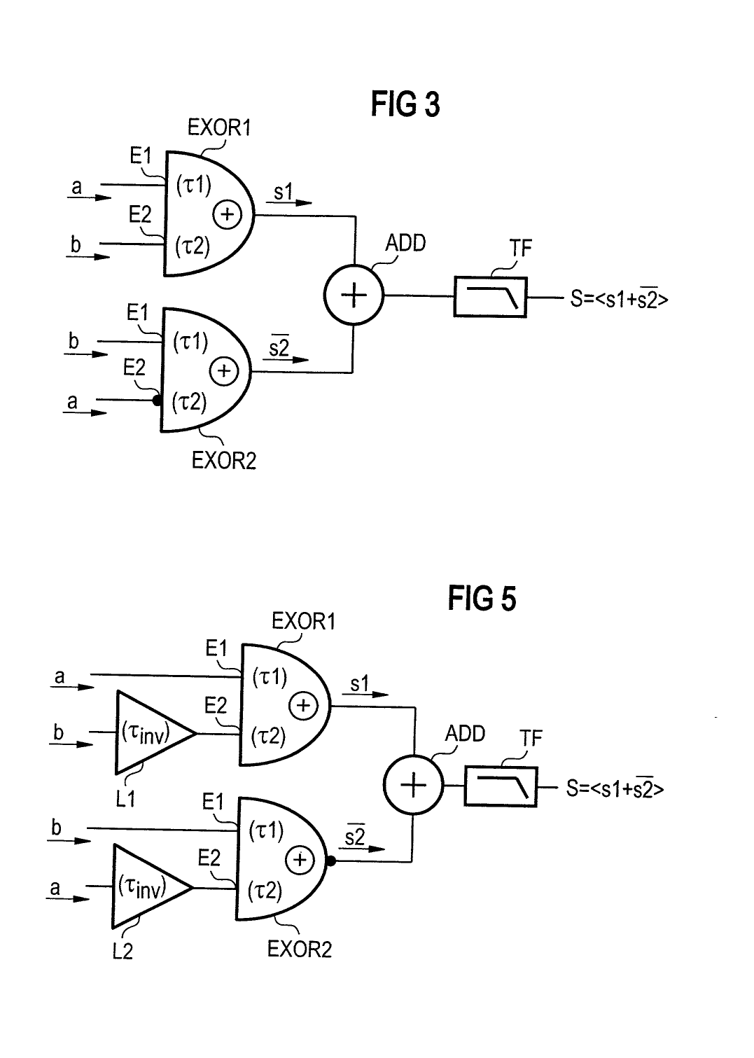

FIG. 3 shows a second variant of the novel phase detector which also leads to the same result. The basic circuit is similar to that in FIG. 1 but has an inverting input of an EXOR element or an inverted signal is supplied to an EXOR element. This inversion followed by addition, of the output signals s1 and s2 via adder circuit ADD is equivalent to the previous subtraction of the EXOR output signals in FIG. 1. Therefore, the phase detector characteristic can also be described as

$${S}_{asym} = < s1 + {s}^{v} 2 >$$

after the low-pass filter TF.

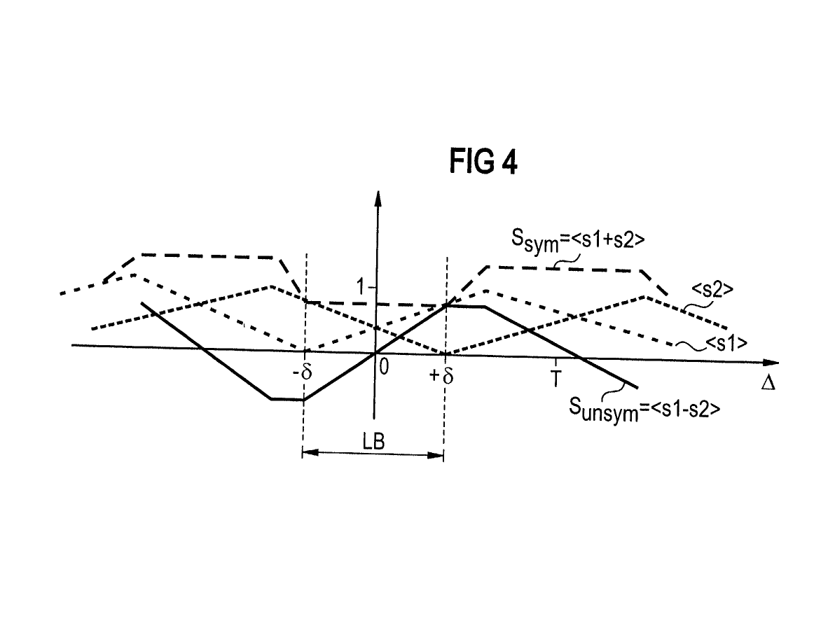

FIG. 4 shows a phase detector characteristic SasyM as a function of the phase difference A between the binary signals a and b. The analog-added and time-averaged output signals <s1> and <s2> of each EXOR element are also represented as a function of the phase difference A. T designates the period of the clock cycle or bit duration, respectively. Each of the signals <s1> and <s2> exhibits an error amount of ε=τ2−τ1>0 around Δ=0 due to the EXOR delays τ1 and τ2. For a symmetric EXOR circuit with addition of the output signals s1 and s2 instead of subtraction of s1 and s2, the phase detector characteristic S_{sym} forms a flat region over [−δ;+δ] around the Δ=0 point. Without inversion of one output signal, e.g. s2, or one input signal of an EXOR element, determination of the equal-phase condition of Δ=0 by <s1+s2> of the set 2δ, with ε=τ2−τ1, remains inaccurate (see plateau in the S_{sym} curve). With the novel asymmetric circuit, this plateau effect is suppressed and the phase detector characteristic

$${S}_{asym} = < s1 - s2 \geq < s1 + {s}^{v} 2 >$$

forms a linear region LB over phase differences in [−δ; +δ]. The equal-phase condition Δ=0 exists with the zero transition of S_{asym}. Assume that the equal-phase condition is determined by a simple sign change of S_{asym} and no longer by a more elaborate and uncertain detection of the minimum as in the case of symmetric circuits. In practice, the equal-phase condition between the binary signals a and b is determined by a threshold value close to the zero transition.

FIG. 5 shows a circuit for expanding the linear region LB of the phase detector characteristic by using two delay sections L1 and L2. In this case, the basic circuit of FIG. 2 was taken but the basic circuits of FIGS. 1 and 3 could also be taken. The two inverters used as delay sections, each having the delay τᵢₙᵥ, are connected either to the first inputs or to the second inputs of each EXOR element. This allows the linear region LB of the phase detector characteristic Sasyn of [−δ; +δ], as shown in FIG. 4, to be extended to [−τᵢₙᵥ−δ;δ+τᵢₙᵥ], with δ=τ2−τ1.

Instead of two delay sections having the delay τᵢₙᵥ, only one may be connected either to a first input of an EXOR element or to a second input of an EXOR gate. In this case, the linear region LB is expanded on one side to phase differences either from −δ to τᵢₙᵥ+δ or from −τᵢₙᵥ−δ to +δ in accordance with how the inverter is connected.

The linear region LB of the characteristic S_{asym} going through the zero point can, thus, be expanded for greater phase differences Δ.

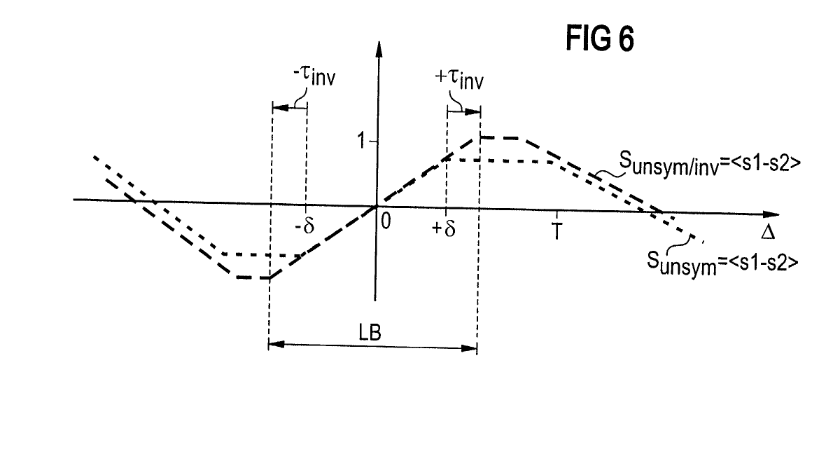

FIG. 6 shows the phase detector characteristic S_{asym/inv} of the circuit provided with two delay sections and the characteristic S_{asym} without inverter (also in FIG. 4). The slope of the linear region LB remains constant. The linear region LB between phase difference A and control voltage S_{asym/inv} of the circuit is expanded to [−τᵢₙᵥ−δ;δ+τᵢₙᵥ].

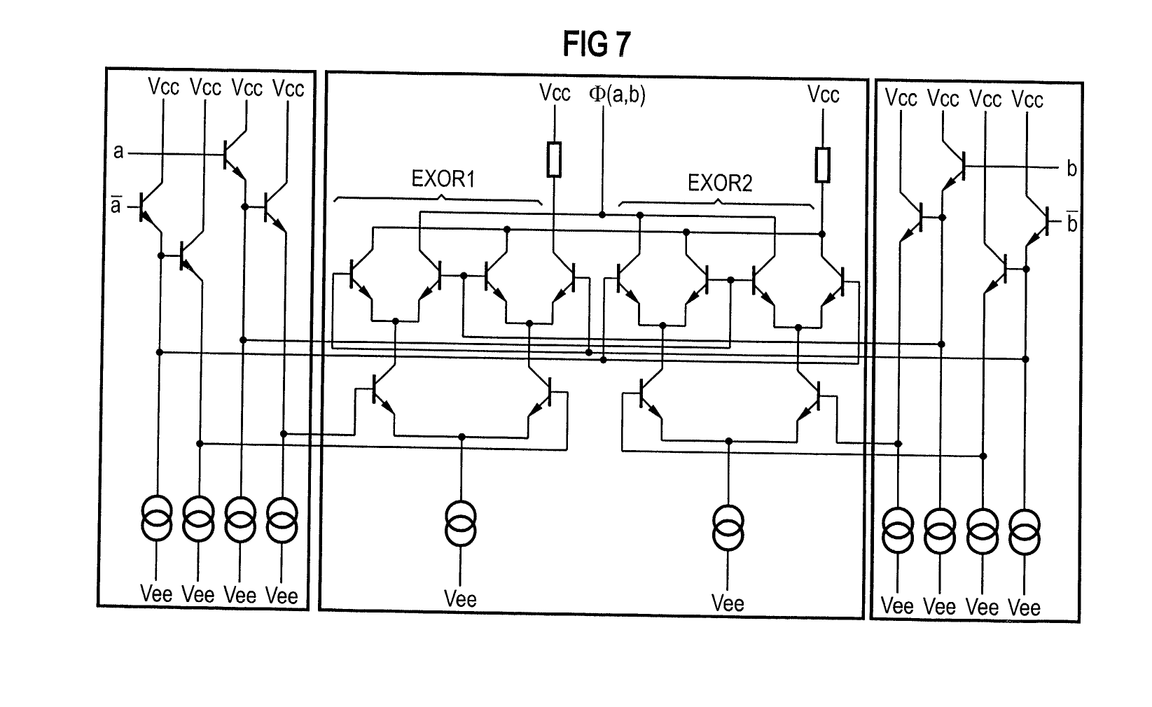

FIG. 7 shows an implementation of the phase detector in CML technology as an illustrative embodiment. The circuit is driven with symmetric signals a, \overline{a} and b, \overline{b}. At input a, at the lower level of the left-hand EXOR element EXORI, an inversion has been performed. Φ(a,b) designates the voltage for determining the phase difference between input signals a and b.

Although the present invention has been described with reference to specific embodiments, those of skill in the art will recognize that changes may be made thereto without departing from the spirit and scope of the invention as set forth in the hereafter appended claims.

1. A phase detector for determining a phase difference between a first binary signal and a second binary signal, comprising:
a first EXOR element having first and second inputs and an output;
a second EXOR element having first and second inputs and an output; and
a subtractor element having first and second inputs and an output;
wherein the first input of the first EXOR element and the second input of the second EXOR element are supplied with the first binary signal, the second input of the first EXOR element and the first input of the second EXOR element are supplied with the second binary signal, the outputs of the first and second EXOR elements are respectively connected to the first and second inputs of the subtractor element, and a control voltage is output at the output of the subtractor element which corresponds to the phase difference.

2. A phase detector for determining a phase difference between a first binary signal and a second binary signal, comprising:
a first EXOR element having first and second inputs and an output;
a second EXOR element having first and second inputs and an output; and
an addition circuit having first and second inputs and an output;
wherein the first input of the first EXOR element and the second input of the second EXOR element are supplied with the first binary signal, the second input of the first EXOR element and the first input of the second EXOR element are supplied with the second binary signal, one of the input signals of the first and second EXOR elements is inverted, the outputs of the first and second EXOR elements are respectively connected to the first and second inputs of the addition circuit, and a control voltage is output at the output of the addition circuit which corresponds to the phase difference.

3. A phase detector for determining a phase difference between a first binary signal and a second binary signal, comprising:
a first EXOR element having first and second inputs and an output;
a second EXOR element having first and second inputs and an output; and
an addition circuit having first and second inputs and an output;
wherein the first input of the first EXOR element and the second input of the second EXOR element are supplied with the first binary signal, the second input of the first EXOR element and the first input of the second EXOR element are supplied with the second binary signal, one of the output signals of the first and second EXOR elements is inverted, the outputs of the first and second EXOR elements are respectively connected to the first and second inputs of the addition circuit, and a control voltage is output at the output of the addition circuit which corresponds to the phase difference.

4. A phase detector as claimed in claim 1, further comprising:
a low-pass filter connected to the output of the subtractor element, the lowpass filter for time-averaging the output voltage of the subtractor element resulting in a controlled voltage which is proportional to the phase difference between the first and second binary signals and which goes through zero in an equal-phase condition.

5. A phase detector as claimed in claim 2, further comprising:
a low-pass filter connected to the output of the addition circuit, the lowpass filter for time-averaging the output voltage of the addition circuit resulting in a control voltage which is proportional to the phase difference between the first and second binary signals and which goes through zero in an equal-phase condition.

6. A phase detector as claimed in claim 3, further comprising:
a low-pass filter connected to the output of the addition circuit, the lowpass filter for time-averaging the output voltage of the addition circuit resulting in a control voltage which is proportional to the phase difference between the first and second binary signals and which goes through zero in an equal-phase condition.

7. A phase detector as claimed in claim 4, wherein the equal-phase condition is defined by a threshold value of the control voltage.

8. A phase-detector as claimed in claim 5, wherein the equal-phase condition is defined by a threshold value of the control voltage.

9. A phase detector as claimed in claim 6, wherein the equal-phase condition is defined by a threshold value of the control voltage.

10. A phase detector as claimed in claim 4, further comprising:
a delay section connected to one of the inputs of the first and second EXOR elements.

11. A phase detector as claimed in claim 5, further comprising:
a delay section connected to one of the inputs of the first and second EXOR elements.

12. A phase detector as claimed in claim 6, further comprising:
a delay section connected to one of the inputs of the first and second EXOR elements.

13. A phase detector as claimed in claim 4, further comprising:
first and second delay sections respectively connected to identical inputs of the first and second EXOR elements.

14. A phase detector as claimed in claim 5, further comprising:
first and second delay sections respectively connected to identical inputs of the first and second EXOR elements.

15. A phase detector as claimed in claim 6, further comprising:
first and second delay sections respectively connected to identical inputs of the first and second EXOR elements.
